(19) United States
(12) Patent Application Publication
(10) Pub. No.: US 2024/0055503 A1
(43) Pub. Date: Feb. 15, 2024

(54) SEMICONDUCTOR DEVICES AND METHODS OF MANUFACTURING SEMICONDUCTOR DEVICES

(71) Applicant: SEMICONDUCTOR COMPONENTS INDUSTRIES, LLC, Phoenix, AZ (US)

(72) Inventors: Arash ELHAMI KHORASANI, Phoenix, AZ (US); Mark GRISWOLD, Gilbert, AZ (US)

(73) Assignee: SEMICONDUCTOR COMPONENTS INDUSTRIES, LLC, Phoenix, AZ (US)

(21) Appl. No.: 17/818,880

(22) Filed: Aug. 10, 2022

(51) Int. Cl. H01L 29/66; H01L 29/78; H01L 29/06

(52) U.S. Cl. CPC H01L 29/66681; H01L 29/7816; H01L 29/0692; H01L 29/66659

(57) ABSTRACT

In an example, a semiconductor device includes a region of semiconductor material, a first dielectric over the region of semiconductor material, a first gate conductor over a first portion of the first dielectric, and a second gate conductor over a second portion of the first dielectric and laterally spaced apart from the first gate conductor. A first conductor is coupled to the first gate conductor and a second conductor coupled to the second gate conductor and laterally separated from the first conductor by a first spacing. A second dielectric is within the first spacing. The first conductor and the second conductor are laterally capacitively coupled, the first gate conductor is vertically capacitively coupled to the region of semiconductor material, and the second gate conductor is vertically capacitively coupled to the region of semiconductor material.

### CROSS-REFERENCE TO RELATED APPLICATIONS

### Technical Field

The present disclosure relates, in general, to electronics and, more particularly, to semiconductor device structures and methods of forming semiconductor devices.

### BACKGROUND

Semiconductor technologies, such as Bipolar-CMOS-DMOS (BCD) technologies, are used in a broad range of products including power management and automotive applications. BCD technology combines the benefits of three process technologies within a single semiconductor component including bipolar technology for analog functions, CMOS (Complementary Metal Oxide Semiconductor) technology for digital functions, and DMOS (Double Diffused Metal Oxide Semiconductor) for power and high voltage functions. The combination of technologies provides, among other things, improved reliability, reduced electromagnetic interference and smaller die area.

Near term future demands in automotive BCD applications are requiring higher power densities, which will require solutions for reducing the specific on resistance (R_{SP}) of the lateral DMOS structures designed for 45 volts to 60 volts (BV_{DSS}) or more. In smaller geometry devices (for example, 65 nanometer or smaller), isolation techniques, such as shallow-trench isolation (STI) and LOCOS isolation have had integration, cost, and reliability issues. In addition, device degradation due to hot carrier injection (HCI) has been a challenge to control in previous approaches.

Accordingly, device structures and methods are needed that improve specific on-resistance performance, support higher breakdown voltages, and are more resistant to hot carrier injection. It would be beneficial for such device structures and methods to require minimal process modifications and to support reduced manufacturing costs.

### BRIEF DESCRIPTION OF THE DRAWINGS

FIG. 1 illustrates a partial cross-sectional view of an example semiconductor device in accordance with the present description;

FIG. 2 illustrates a portion of the semiconductor device of FIG. 1;

FIG. 3 illustrates a partial cross-sectional view of an example semiconductor device in accordance with the present description;

FIG. 4 is a top plan view of an example semiconductor device layout in accordance with the present description;

FIG. 5 graphically illustrates specific on-resistance (R_{SP}) data as a function of breakdown voltage (BV_{DSS}) for N-channel semiconductor devices in accordance with the present description compared to previous semiconductor devices;

FIG. 6 graphically illustrates specific on-resistance (R_{SP}) data as a function of breakdown voltage (BV_{DSS}) for P-channel semiconductor devices in accordance with the present description compared to previous semiconductor devices;

FIG. 7 illustrates a partial cross-sectional and perspective view of an example semiconductor device in accordance with the present description;

FIG. 8 illustrates a partial cross-sectional and perspective view of an example semiconductor device in accordance with the present description;

FIG. 9 illustrates a partial cross-sectional and perspective view of an example semiconductor device in accordance with the present description;

FIG. 10 illustrates a partial cross-sectional and perspective view of an example semiconductor device in accordance with the present description;

FIG. 11A illustrates a top plan view of a laterally capacitively coupled conductor structure in accordance with the present description;

FIG. 11B illustrates a side view of the laterally capacitively coupled conductor structure of FIG. 11A;

FIG. 11C illustrates a perspective view of a laterally capacitively coupled conductor structure in accordance with the present description;

FIG. 12 illustrates a partial cross-sectional and perspective view of an example semiconductor device in accordance with the present description;

FIG. 13 illustrates a partial cross-sectional and perspective view of an example semiconductor device in accordance with the present description;

FIG. 14 illustrates a partial cross-sectional and perspective view of an example semiconductor device in accordance with the present description; and

FIG. 15 illustrates a partial cross-sectional and perspective view of an example semiconductor device in accordance with the present description.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

For simplicity and clarity of the illustration, elements in the figures are not necessarily drawn to scale, and the same reference numbers in different figures denote the same elements. Additionally, descriptions and details of well-known steps and elements are omitted for simplicity of the description.

For clarity of the drawings, certain regions of device structures, such as doped regions or dielectric regions, may be illustrated as having generally straight-line edges and precise angular corners. However, those skilled in the art understand that, due to the diffusion and activation of dopants or formation of layers, the edges of such regions generally may not be straight lines and that the corners may not be precise angles.

Although the semiconductor devices are explained herein as certain N-type conductivity regions and certain P-type conductivity regions, a person of ordinary skill in the art understands that the conductivity types can be reversed and are also possible in accordance with the present description, taking into account any necessary polarity reversal of voltages, inversion of transistor type and/or current direction, etc.

In addition, the terminology used herein is for the purpose of describing particular examples only and is not intended to be limiting of the disclosure. As used herein, the singular forms are intended to include the plural forms as well, unless the context clearly indicates otherwise.

As used herein, “current-carrying electrode” means an element of a device that carries current through the device, such as a source or a drain of an MOS transistor, an emitter or a collector of a bipolar transistor, or a cathode or anode of a diode, and a “control electrode” means an element of the device that controls current through the device, such as a gate of a MOS transistor or a base of a bipolar transistor.

The term “major surface” when used in conjunction with a semiconductor region, wafer, or substrate means the surface of the semiconductor region, wafer, or substrate that forms an interface with another material, such as a dielectric, an insulator, a conductor, or a polycrystalline semiconductor. The major surface can have a topography that changes in the x, y and z directions.

The terms “comprises”, “comprising”, “includes”, “including”, “has”, “have” and/or “having” when used in this description, are open ended terms that specify the presence of stated features, numbers, steps, operations, elements, and/or components, but do not preclude the presence or addition of one or more other features, numbers, steps, operations, elements, components, and/or groups thereof.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

Although the terms “first”, “second”, etc. may be used herein to describe various members, elements, regions, layers and/or sections, these members, elements, regions, layers and/or sections should not be limited by these terms. These terms are only used to distinguish one member, element, region, layer and/or section from another. Thus, for example, a first member, a first element, a first region, a first layer and/or a first section discussed below could be termed a second member, a second element, a second region, a second layer and/or a second section without departing from the teachings of the present disclosure.

It will be appreciated by one skilled in the art that words, “during”, “while”, and “when” as used herein related to circuit operation are not exact terms that mean an action takes place instantly upon an initiating action but that there may be some small but reasonable delay, such as propagation delay, between the reaction that is initiated by the initial action. Additionally, the term “while” means a certain action occurs at least within some portion of a duration of the initiating action.

The use of word “about”, “approximately”, or “substantially” means a value of an element is expected to be close to a state value or position. However, as is well known in the art there are always minor variances preventing values or positions from being exactly stated.

Unless specified otherwise, as used herein, the word “over” or “on” includes orientations, placements, or relations where the specified elements can be in direct or indirect physical contact.

Unless specified otherwise, as used herein, the word “overlapping” includes orientations, placements, or relations where the specified elements can at least partly or wholly coincide or align in the same or different planes.

It is further understood that the examples illustrated and described hereinafter suitably may have examples and/or may be practiced in the absence of any element that is not specifically disclosed herein.

### DETAILED DESCRIPTION OF THE DRAWINGS

In general, the present examples relate to semiconductor device structures and methods of making semiconductor devices, such as lateral double diffused metal-oxide semiconductor (LDMOS) devices, which include capacitively coupled gate conductor structures. In some examples, the capacitively coupled gate conductor structures are laterally capacitively coupled to each other and vertically capacitively coupled to portions of the semiconductor device to, among other things, control electrical field build-up during device operation. In other examples, the capacitively coupled gate conductor structures are vertically capacitively coupled to portions of the semiconductor device to control electrical field build-up.

In some examples, the capacitively coupled gate conductor structures are formed over a dielectric having a selected thickness and structure that reduces hot carrier injection at higher breakdown voltages particularly with smaller device nodes (for example, 65 nanometer or smaller). In addition, in some examples the dielectric has a planar or non-recessed structure that improves specific on-resistance at higher breakdown voltages by providing a smaller path for current flow. The structures and methods according to the present disclosure can be used without expensive silicon on insulator (SOI), shallow trench isolation (STI), or localized oxidation (LOCOS) type isolations. This provides for, among other things, a cost effective and reliable implementation for smaller process nodes and for application that have higher reliability requirements, such as automotive applications.

In addition, because the gate conductor structures in some examples are laterally capacitively coupled, the spacing between the gate conductor structures (which sets the capacitive coupling between the gate conductor structures) is determined using, for example, photolithographic techniques that are reproduceable and have reduced variation in capacitance compared to previous vertical capacitive structures that depend on the thickness of dielectric layers formed using deposition processes or growth processes, which have a higher variability and thus, a more variable capacitive coupling.

In an example, a semiconductor device includes a region of semiconductor material, a first dielectric over the region of semiconductor material, a first gate conductor over a first portion of the first dielectric, and a second gate conductor over a second portion of the first dielectric and laterally spaced apart from the first gate conductor. A first conductor is coupled to the first gate conductor and a second conductor is coupled to the second gate conductor and laterally separated from the first conductor by a first spacing. A second dielectric is within the first spacing. The first conductor and the second conductor are laterally capacitively coupled, the first gate conductor is vertically capacitively coupled to the region of semiconductor material, and the second gate conductor is vertically capacitively coupled to the region of semiconductor material.

In an example, a semiconductor device includes a region of semiconductor material comprising a first conductivity type, a gate dielectric adjacent to the region of semiconductor material, and a first dielectric adjacent to the region of semiconductor material. A first gate electrode is over the gate dielectric and over a first portion of the first dielectric. A second gate electrode is over a second portion of the first dielectric and laterally spaced apart from the first gate electrode. A first conductor is coupled to the first gate electrode. A second conductor coupled to the second gate electrode and laterally separated from the first conductor by a space. A second dielectric is within the space. The first conductor is capacitively coupled to the second conductor across the space in a first direction. The second gate electrode is capacitively coupled to the region of semiconductor material in a second direction different than the first direction. In some examples, the first gate electrode that is over the first portion of the first dielectric is capacitively coupled to the region of semiconductor material in the second direction.

In an example, a method of manufacturing a semiconductor device includes providing a region of semiconductor material comprising a first conductivity type. The method includes providing a gate dielectric adjacent to the region of semiconductor material. The method includes providing a first dielectric adjacent to the region of semiconductor material. The method includes providing a first gate electrode over the gate dielectric and over a first portion of the first dielectric. The method includes providing a second gate electrode over a second portion of the first dielectric and laterally spaced apart from the first gate electrode. The method includes providing a second dielectric over the gate electrode and the first dielectric. The method includes providing a first conductor electrically connected to the first gate electrode. The method includes providing a second conductor electrically connected to the second gate electrode and laterally separated from the first conductor by a space. The method includes providing a second dielectric in the space. The first conductor is capacitively coupled to the second conductor across the space in a first direction. The first gate electrode over the first portion of the first dielectric is capacitively coupled to the region of semiconductor material in a second direction. The second gate electrode is capacitively coupled to the region of semiconductor material in the second direction.

Other examples are included in the present disclosure. Such examples may be found in the figures, in the claims, or in the description of the present disclosure.

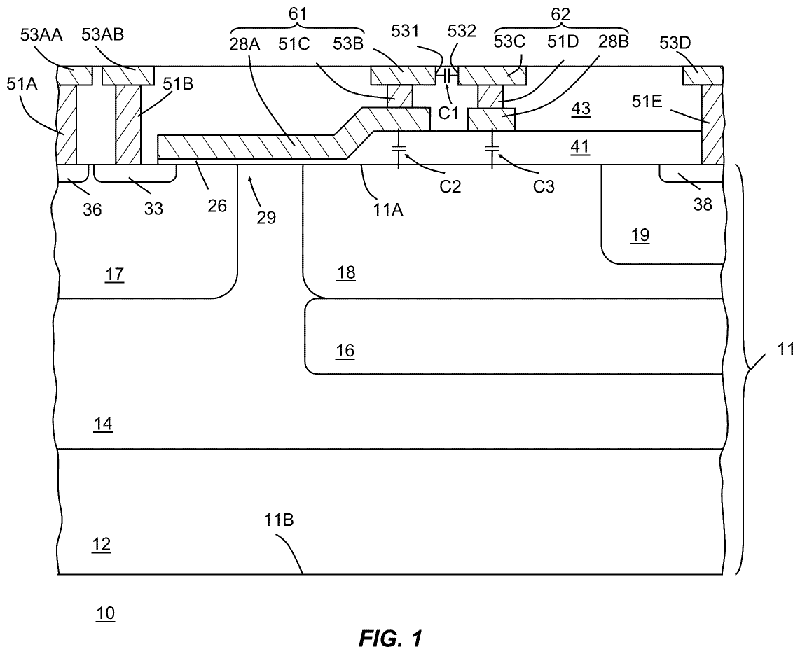

FIG. 1 illustrates a partial cross-sectional view of an example semiconductor device 10 in accordance with the present description that is configured for higher breakdown voltage (BV_{DSS}) performance, has improved specific on-resistance (R_{SP}), and is less susceptible to hot carrier injection (HCI). Semiconductor device 10 can also be referred to as an electronic device, a semiconductor component, or an electronic component. Semiconductor device 10 is shown as an N-channel LDMOS device, but it understood that the structures and methods of the present description can be used for other types of semiconductor devices where the control of electrical field or the reduction of hot carrier injection effects are useful. In other examples, semiconductor device 10 can be a P-channel LDMOS device by reversing the conductivity types of the various regions described.

In accordance with the present description, semiconductor device 10 includes gate structure 61 and a gate structure 62 that is laterally capacitively coupled to gate structure 61. Gate structure 61 and gate structure 62 are also vertically capacitively coupled a well region 18 (for example, a drift region) of semiconductor device 10 through a dielectric 41. In some examples, dielectric 41 has a preselected thickness so that gate structure 61 and gate structure 62 can control an electric field within a well region 18 responsively to a voltage applied to gate structure 61. In some examples, dielectric 41 has a thickness between about 800 Angstroms and 2000 Angstroms depending on the BV_{DSS} rating of semiconductor device 10. In accordance with the present description, this preselected thickness range is thinner that previous LOCOS or STI dielectric structures.

The combination of gate structure 61 capacitively coupled to gate structure 62 together with using the relatively thin dielectric 41 provides for a tunable configuration that controls electric field build-up when semiconductor device 10 is in a blocking mode of operation thereby increasing BV_{DSS}. In addition, in some examples dielectric 41 is a planar dielectric as opposed to being recessed or partially recessed into well region 18, which occurs with LOCOS and STI type dielectric isolation structures. That is, in some examples dielectric 41 is a non-recessed dielectric. This removes the dielectric from the lateral current path in semiconductor device 10, which reduces HCI and improves R_{SP}. Additional details of dielectric 41, gate structure 61 and gate structure 62 will provided later.

Semiconductor device 10 comprises a region of semiconductor material 11, which includes a major surface 11A and a major surface 11B opposite to major surface 11A. Region of semiconductor material 11 can also be referred to as a body of semiconductor material, a semiconductor work piece, a semiconductor wafer, or a semiconductor substrate. Major surface 11A can also be referred to as an active side or a top side of semiconductor device 10, and major surface 11B can also be referred to an in-active side or a bottom side of semiconductor device 10. Region of semiconductor material 11 or a portion or portions thereof can comprise silicon, a IV-IV semiconductor material, a III-V semiconductor material, or combinations thereof.

In some examples, region of semiconductor material 11 includes a substrate 12 and a semiconductor region 14 over substrate 12. In the present example, substrate 12 includes major surface 11B and semiconductor region 14 includes major surface 11A. Substrate 12 can also be referred to as a semiconductor substrate or a starting substrate, and semiconductor region 14 can also be referred to as semiconductor layer, an epitaxial semiconductor layer, or an epitaxial semiconductor region.

In the present example, substrate 12 can comprise silicon and can have a P-type conductivity. In some examples, substrate 12 is doped with boron and can having a resistivity in a range from about 10 ohm-cm to about 40 ohm-cm. In some examples, semiconductor region 14 can comprises a P-type conductivity, can be doped with boron, and can have a resistivity in a range similar to that of substrate 12. In some examples, semiconductor region 14 can be formed using epitaxial growth techniques and can be doped in-situ during the epitaxial growth process. In some examples, semiconductor region 14 can have a thickness in range from about 4.0 microns to about 6.0 microns.

In some examples, semiconductor device 10 may include an optional buried layer 16 in a portion of semiconductor layer 14. In the present example, buried layer 16 is a P-type conductivity buried layer and can be formed using ion implantation and anneal processes or other doping processes as known to one of ordinary skill in the art. For example, buried layer 16 can be formed as part of the formation process of semiconductor region 14. Buried layer 16 is configured to help tune the electric field as it spreads in semiconductor device 10.

Semiconductor device 10 includes a well region 17 extending into semiconductor region 14 from major surface 11A. Well region 17 can also be referred to a first well region. In the present example, well region 17 is a P-type conductivity well region and can be formed using ion implantation and anneal processes or other doping processes as known to one of ordinary skill in the art. In some examples, well region 17 can be doped with boron, can have a peak dopant concentration in range from about 1.0×10¹⁶ atoms/cm³ to about 1.0×10¹⁸ atoms/cm³, and can have a depth in a range from about 1.0 micron to about 2.0 microns.

In the present example, well region 18 can be an N-type conductivity well region and can be formed using ion implantation and anneal processes or other doping processes as known to one of ordinary skill in the art. In some examples, well region 18 can be formed using multiple ion implants of different doses or energies to provide well region 18 with a tailored dopant profile. Well region 18 can also be referred to as a second well region or a drift region for semiconductor device 10. In some examples, well region 18 can be doped with phosphorous, can have a peak dopant concentration in range from about 1.0×10¹⁶ atoms/cm³ to about 1.0×10¹⁷ atoms/cm³, and can have a depth in a range from about 1.0 micron to about 2.0 microns.

In some examples, a doped region 33 comprising an N-type conductivity is within well region 17 and is configured as a current carrying electrode or a source region for semiconductor device 10. A doped region 36 comprising a P-type conductivity is within well region 17 adjacent to doped region 33. Doped region 36 can also be referred to as a body contact region and can abut doped region 33 or can be laterally spaced apart from doped region 33. Doped region 33 and doped region 36 can be formed using ion implantation and anneal processes or other doping processes as known to one of ordinary skill in the art. In some examples, doped region 33 can be doped with phosphorous and doped region 36 can be doped with boron in accordance with typical CMOS process requirements.

In some examples, semiconductor device may include an optional well region 19 comprising an N-type conductivity is provided in a portion of well region 18 and a doped region 38 comprising an N-type conductivity is provided within well region 19. In some examples, doped region 38 is configured as a current carrying electrode or drain region for semiconductor device 10. Well region 19 can also be referred to as a third well region. Well region 19 and doped region 38 can be formed using ion implantation and anneal processes or other doping processes a known to one of ordinary skill in the art. In some examples, well region 19 has a higher peak dopant concentration than well region 18, and doped region 38 has a higher peak dopant concentration that well region 19. Doped region 38 can be doped with phosphorous in accordance with typical CMOS process requirements.

Semiconductor device 10 further comprises a gate dielectric 26 adjacent to major surface 11A, doped region 33, a portion of well region 17, a portion of semiconductor region 14, and a portion of well region 17. In some examples, gate dielectric 26 comprises an oxide, a nitride, tantalum pentoxide, titanium dioxide, barium strontium titanate, high k dielectric materials, combinations thereof, or other related or equivalent materials known to one of ordinary skill in the art. In some examples, gate dielectric 26 is an oxide and has a thickness in a range from about 40 Angstroms to about 80 Angstroms.

Dielectric 41 is adjacent to a portion of well region 18 and in some examples can extend between gate dielectric 26 and doped region 38. In some examples, dielectric 41 has a thickness in range from about 800 Angstroms to about 2000 Angstroms. In other examples, dielectric 41 has a thickness in a range from about 1000 Angstroms to about 1200 Angstroms. In one example, dielectric 41 has a thickness of about 1100 Angstroms. In some examples, the thickness of dielectric is selected based on the configurations of gate structure 61 and gate structure 62 and the desired BV_{DSS} for semiconductor device 10.

In some examples, dielectric 41 is an oxide formed as a deposited oxide using high temperature chemical vapor deposition (CVD). That is, dielectric 41 can be a high temperature oxide (HTO). In some examples, dielectric 41 is formed using atmospheric, low-pressure CVD (LPCVD), or plasma-enhanced (PECVD) process techniques. In some examples, dielectric 41 can densified using an anneal process (for example, about 750 to about 900 degrees Celsius) after dielectric 41 is formed. In other examples, dielectric 41 can be a nitride, combinations of oxide and nitride, or other dielectrics as known to one of ordinary skill in the art. In some examples, dielectric 41 is undoped. In some examples, dielectric 41 has an edge that this proximal to gate dielectric 26, which can be sloped or tapered as generally illustrated in FIG. 1. This helps provide good step coverage for a gate conductor 28A, which is described next. Dielectric 41 is an example of or can be referred to as a first dielectric.

In some examples, gate conductor structure 61 comprises gate conductor 28A that is adjacent to gate dielectric 26 and extends to overlap a portion of dielectric 41. That is, gate conductor 28A is over gate dielectric 26 and is over a portion of dielectric 41. In some examples, gate conductor 28A is a continuous structure over its lateral width across gate dielectric 26 to the portion of dielectric 41 as generally illustrated in FIG. 1. In some examples, gate conductor structure 62 comprises a gate conductor 28B that is adjacent to dielectric 41 and is laterally spaced apart from gate conductor 28A. In some examples, both gate conductor 28A and gate conductor 28B overlie portions of region of semiconductor material 11, such as portions of well region 18 as illustrated in FIG. 1. In some examples, at least gate conductor 28B is over well region 18. That portion of gate conductor 28A over gate dielectric 26 is configured to control the flow of current between doped region 33 and doped region 38 by establishing a channel region 29 in region of semiconductor material 14 in accordance with an applied gate voltage.

In some examples, gate conductor 28A and gate conductor 28B comprise one or more conductive materials, such a metal, a silicide, a doped polycrystalline semiconductor material, combinations thereof, or other conductive materials as known to one of ordinary skill in the art. In some examples, gate conductor 28A and gate conductor 28B comprise polysilicon conductors doped with an N-type conductive dopant. Gate conductor 28A and gate conductor 28B can formed using deposition techniques including CVD processes and can be patterned using photolithographic and etch processes. In some examples, gate conductor 28A and gate conductor 28B have a thickness in range from about 1000 Angstroms to about 2400 Angstroms. In some examples, when gate dielectric 26 comprises a high K dielectric, gate conductors 28A and 28B can comprise a metal. Gate conductors 28A and 28B can also be referred to as gate electrodes or conductors.

In some examples, a dielectric 43 is formed over gate conductor 28A, gate conductor 28B, and a portion of dielectric 41. In some examples, dielectric 43 comprises one or more dielectric materials, such as oxides, nitrides, combinations thereof, or other dielectric materials as known to one of ordinary skill in the art. In some examples, dielectric 43 is an oxide that can be a doped oxide or an undoped oxides or combinations of layers that are doped and undoped. In some examples, dielectric 43 has a thickness in a to accommodate a desired number of conductors and can be formed using CVD processes or other processes as known to one of ordinary skill in the art. In some examples, dielectric layer 43 has a thickness of 6000 Angstroms or more. In some examples, dielectric 43 or a portion or layer of dielectric 43 provides the capacitor dielectric between gate conductor structure 61 and gate conductor structure 62. In other examples, another dielectric can be deposited over dielectric 43 and the additional dielectric can provide the capacitor dielectric between gate conductor structure 61 and gate conductor structure 62. Dielectric 43 can also be referred to as an inter-layer dielectric (ILD). Dielectric 43 is an example of or can be referred to as a second dielectric.

In some examples, gate conductor structure 61 comprises a conductor 53B that is coupled to gate conductor 28A. In some examples, conductor 53B is coupled to gate conductor 28A by conductive interconnect or conductive via 51C. Gate conductor structure 62 comprises a conductor 53C that is coupled to gate conductor 28B. In some examples, conductor 53C is coupled to gate conductor 28B by conductive interconnect or conductive via 51D. In some examples, conductors 53B and 53C and conductive interconnects 51C and 51D comprise one or more metals, such as copper (for example, with a barrier structure), copper alloys (for example, with a barrier structure), or other conductive materials as known to one of ordinary skill in the art. In some examples, conductive interconnects 51C and 51D can be tungsten plugs or similar structures as known to one of ordinary skill in the art. In some examples, conductors 53B and 53C and conductive interconnects 51C and 51D can be formed using evaporation, sputtering, plating, or other deposition techniques as known to one of ordinary skill in the art. In some examples, conductors 53B and 53C can having a thickness in range from about 0.2 microns to about 0.5 microns. In some examples, conductive interconnects 51C and 51D can be different materials than conductors 53B and 53C. Photolithographic and etch processes can be used to pattern conductors 53B and 53C. In some examples, conductive interconnects 51C and 51D and conductors 53B and 53C can be formed at the same time by forming openings in dielectric 43 to expose portions of gate conductor 28A and gate conductor 28B, and then depositing conductive material over dielectric 43 and into the openings. In other examples, conductive interconnects 51C and 51D are formed first and then conductors 53B and 53C are formed.

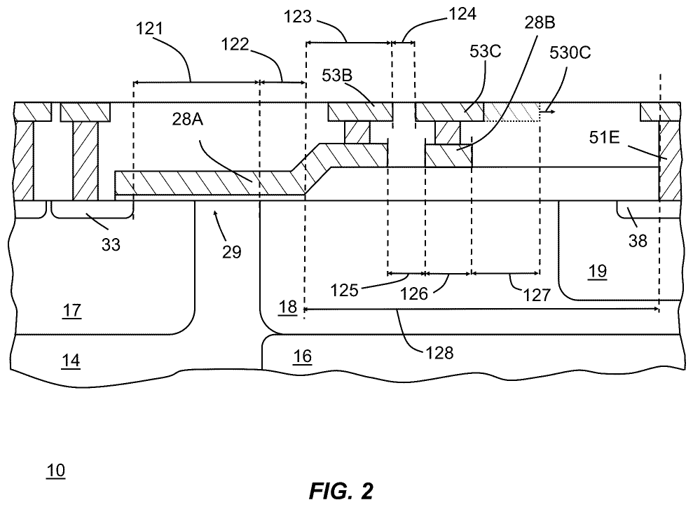

As illustrated in FIG. 1, conductor 53B has a lateral side or end portion 531 and conductor 53C has a lateral side or end portion 532 that faces but is separated from lateral side 531. That is lateral side 531 is separated from lateral side 532 by a spacing or gap 124 (illustrated in FIG. 2). As stated above, in some examples, dielectric 43 is within spacing 124 and conductor 53B is laterally capacitively coupled to conductor 53C through dielectric 43 in spacing 124 as illustrated by capacitor C1 in FIG. 1. In addition, gate conductor 28A is vertically capacitively coupled to well region 18 through dielectric 41 as illustrated by capacitor C2 in FIG. 1, and gate conductor 28B is vertically capacitively coupled to well region 18 through dielectric 41 as illustrated by capacitor C3 in FIG. 1. That is, conductor 53B is capacitively coupled to conductor 53C in a first direction, gate conductor 28A is capacitively coupled to region of semiconductor material 11 (for example, well region 18) in a second direction, and gate conductor 28B is capacitively coupled to region of semiconductor material 11 (for example, different portion of well region 18) in the second direction. The second direction is different than the first direction. In some examples, the first direction is generally parallel to major surface 11A of region of semiconductor material 11, and the second direction is generally orthogonal or perpendicular to major surface 11A.

In some examples, conductor 53B has lateral end 531 adjoining dielectric 43 and conductor 53C has lateral end 532 adjoining dielectric 43 within spacing 124. That is lateral end 531 faces lateral end 532, and lateral end 531 can form a first capacitive plate and lateral end 532 can form a second capacitive plate to form capacitor C1. In semiconductor device 10, since C1>C2+C3, gate structure 61 and gate structure 62 facilitate fine-tuning of the electric field in well region 18 while using a thin dielectric 41.

In some examples, semiconductor device 10 comprises a conductor 53AA that is coupled to doped region 36 by conductive interconnect or conductive via 51A and a conductor 53AB coupled to doped region 33 by conductive interconnect or conductive via 51B. In addition, semiconductor device 10 can comprise a conductor 53D that is coupled to doped region 38 by conductive interconnect or conductive via 51E. Conductors 53AA, 53AB and 53D and conductive interconnects 51A, 51B, and 51E can be similar materials to those described previously for conductors 53B and 53C and conductive interconnects 51C and 51D and can be formed using similar processes.

In accordance with the present description, when semiconductor device 10 is in a blocking mode of operation, gate structure 61 and gate structure 62 are configured to tune or control the electric filed in the underlying well or drift region 18. Since the capacitance that is associated with gate structure 62 (i.e., the series combination of C1 and C3) is lower than the capacitance that is associated with gate structure 61 (i.e., capacitance C2), gate structures 61 and 62 function to spread out the electrostatic potential along the underlying drift region 18 such that the maximum electric field in drift region 18 is reduced. This reduction in electric field enables semiconductor device 10 to have a higher BV_{DSS} for a given drift region length without requiring a thick dielectric 41. In the absence of gate structure 62, to reduce the electric field in the underlying drift region 18, the gate structure 61 must be extended further over drift region 18. However, if dielectric 41 is not thick enough, the right edge of gate structure 61 will eventually cause a high enough electric field in the underlying drift region 18 thereby compromising the BV_{DSS} of semiconductor device 10.

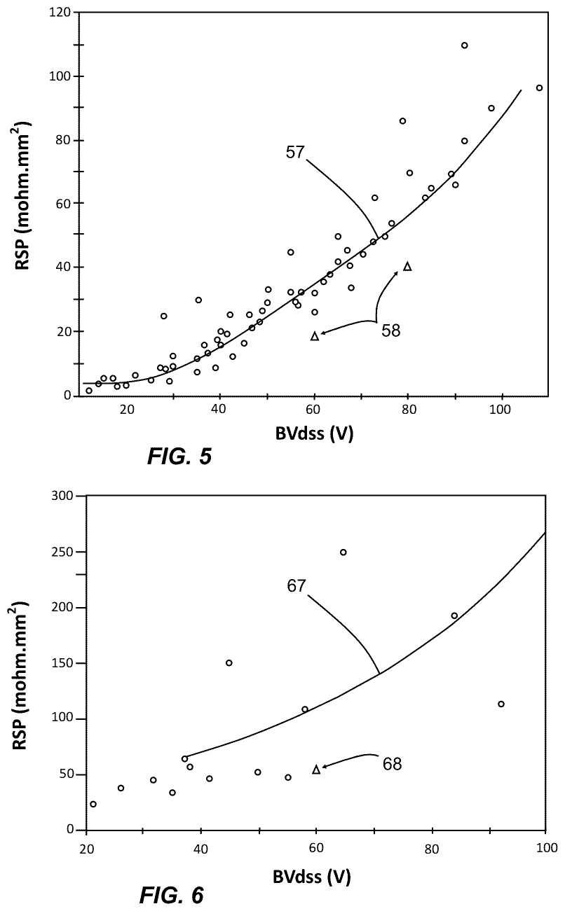

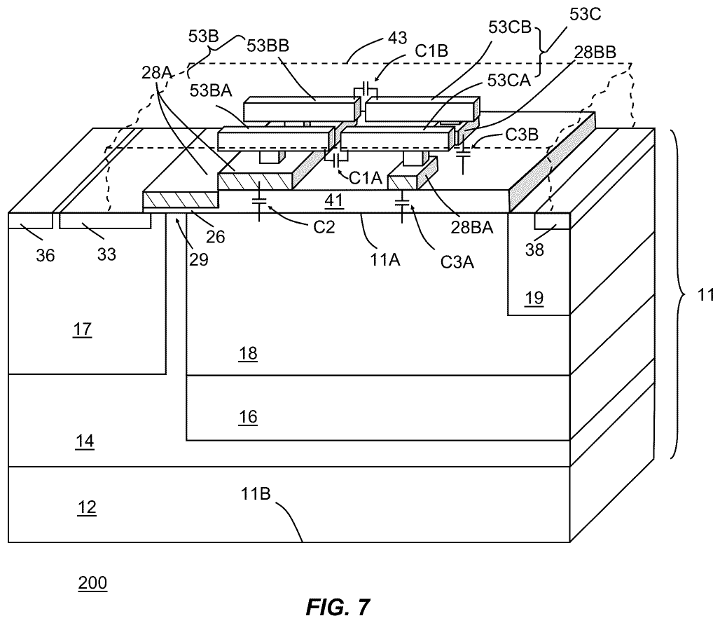

In accordance with the present description, gate structure 61 and gate structure 62 facilitate dielectric 41 having thickness that is thinner than previous devices. A thicker dielectric is detrimental R_{SP} because it would weaken the accumulation effect of gate structure 61 when semiconductor device 10 is in an on-state of operation. Thus, semiconductor device 10 has improved performance compared to previous devices. This is further shown in FIGS. 5 and 6. In addition, semiconductor device 10 with dielectric 41 over the drift region was evaluated in accordance with industry accepted testing for HCI degradation (i.e., HCI shift at 0.2 years less than 10%) against a previous using an STI dielectric over the drift region. More particularly, semiconductor device 10 with dielectric 41 showed an HCI shift at 0.2 years of about 4% and a previous device with an STI structure showed an HCI shift at 0.2 years of 13.5%. This is a significant improvement.

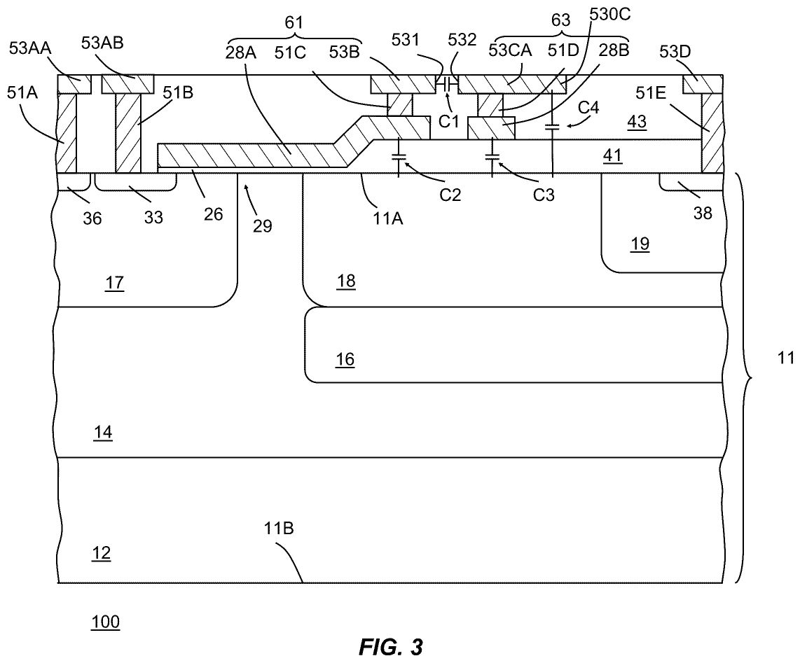

FIG. 2 illustrates a portion of semiconductor device 10 of FIG. 1. More particularly, FIG. 2 illustrates various dimensions of semiconductor device 10 that can be used as design or layout parameters to optimize the electrical characteristics (for example, BV_{DSS}, R_{SP}, and HCI) of semiconductor device 10 in accordance with desired performance specifications. In addition, the capacitive values for capacitors C1, C2, C3, and C4 (shown in FIG. 3) can be set using the thickness of dielectric 41 and dielectric 43, the areas of gate conductors 28A and 28B parallel to major surface 11, by the area of the lateral sides of conductors 53B and 53C that face each other across spacing or dimension 124, and by the size of spacing 124.

As set forth previously, dimension 124 corresponds to the spacing, distance, or width between a lateral side (for example, lateral side 531 shown in FIG. 1) of conductor 53B and a lateral side (for example, lateral side 532 shown in FIG. 1) of conductor 53C. Dimension 124 is adjusted in accordance with desired capacitance values for capacitor C1 (shown in FIG. 1). In some examples, dimension 124 can be in a range from about 0.1 microns to about 0.3 microns.

Dimension 121 is a lateral width that corresponds to the channel length of channel 29. In some examples, dimension 121 can be in a range from about 0.25 microns to about 0.55 microns or larger. Dimension 122 is a lateral width that corresponds to the distance or spacing between the lateral edge of well region 18 proximal to gate dielectric 26 and a point where gate dielectric layer 26 termination and dielectric 41 is located or where the transition to dielectric 41 starts and where the drift region of semiconductor device 10 begins within well region 18. In some examples, dimension 122 can be in a range from about 0.2 microns to about 0.6 microns. Dimension 123 is a lateral width that corresponds to the distance from where gate dielectric layer 26 transitions to dielectric 41 to the lateral side of conductor 53B proximal to conductor 53C. In some examples, dimension 123 can be in a range from about 0.2 microns to about 0.6 microns.

Dimension 125 is a spacing, distance, or width between a lateral side of gate conductor 28A that is over dielectric 41 and a lateral side of gate conductor 28B that is proximal to gate conductor 28A. In some examples, dimension 125 can be in a range from about 0.2 microns to about 0.5 microns. Dimension 126 is a width of gate conductor 28B and, in some examples can be in a range from about 0.2 microns to about 0.5 microns. Dimension 127 is a distance that conductor 53C is extended past a lateral side of gate conductor 28B distal to gate dielectric 26 to overlie well region 18. Dimension 127 corresponds to a width for a field plate portion 530C of conductor 53C. In some examples, dimension 127 can be in a range from about 0 microns to about 0.5 microns. Dimension 128 corresponds to the distance or spacing between where gate dielectric 26 transitions to dielectric 41 and an edge of conductive interconnect 51E that is proximal to gate dielectric 126. In some examples, dimension 128 can be in a range from about 1.0 microns to about 2.0 microns but can be adjusted for purposes of scaling semiconductor device 10 for different BV_{DSS} ratings.

FIG. 3 illustrates a partial cross-sectional view of an example semiconductor device 100 in accordance with the present description that is configured for higher breakdown voltage (BV_{DSS}) performance, has improved specific on-resistance (R_{SP}), and is less susceptible to hot carrier injection (HCI). Semiconductor device 100 has some similarity of construction to semiconductor device 10 and the similarity will not be repeated here. In this regard, only the distinctions between the semiconductor devices will be described.

Semiconductor device 100 comprises a gate conductor structure 63 including conductor 53CA. In the present example, conductor 53CA includes field plate portion 530C that laterally extends away from the lateral side of gate conductor 28B distal to gate dielectric 26. That is, field plate portion 530C extends beyond the distal lateral edge of gate conductor 28B and overlaps a portion of well region 18 between gate conductor 28B and doped region 38. In semiconductor device 100, conductor 53CA is vertically capacitively coupled to well region 18 through dielectric 43 and dielectric 41 as represented by capacitor C4. In accordance with the present description, conductor 53CA is configured to provide additional electric field shaping or control for semiconductor device 100. In semiconductor device 100, since C1>C2+C3>C4, gate structure 61 and gate structure 63 facilitate fine-tuning of the electric field in well region 18 while using a thin dielectric 41.

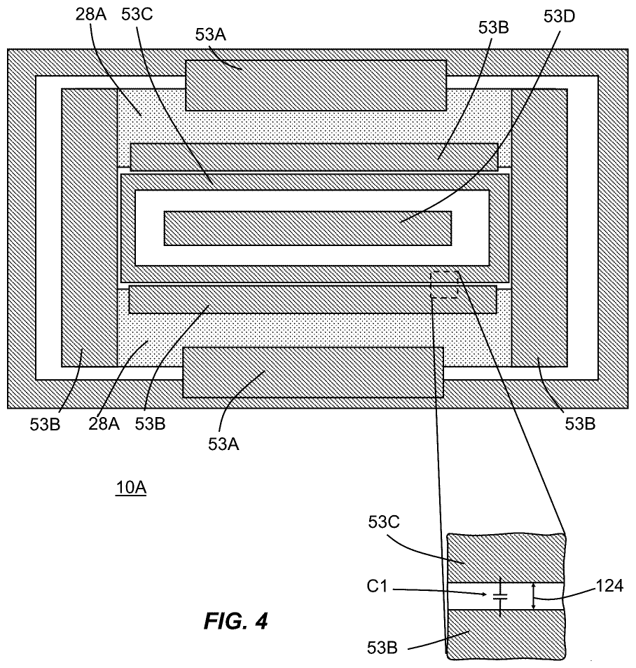

FIG. 4 is a top plan view of an example semiconductor device cell layout 10A or semiconductor device cell 10A in accordance with the present description. Semiconductor device layout 10A can be used with, for example, semiconductor device of FIG. 1 or semiconductor device 100 of FIG. 3. In the example illustrated, the top plan view is of a metal 1 layer configuration with gate conductor 28A visible below the metal 1 layer. In some examples, conductor 53A is provided as a pair of opposing stripes or rectangular shapes at an upper side and a lower side of semiconductor device layout 10A. As set forth previously conductor 53A is coupled to doped region 33 and doped region 36. In some examples, conductor 53D is provided as at least one stripe or rectangular shape at a central portion of semiconductor device layout 10A and parallel to conductors 53A. As set forth previously, conductor 53D is coupled to doped region 38.

In some examples, conductor 53C is provided as a rectangular ring shape surrounding conductor 53D. That is, conductor 53D is within a perimeter of conductor 53C. As set forth previously, conductor 53C is coupled to gate conductor 28B (not shown). In some examples, conductors 53B can be provided as a first pair of opposing stripes that are parallel to conductors 53A and a second pair of opposing stripes that are orthogonal to the first pair of stripes. As set forth previously, conductor 53C is coupled to gate conductor 28A. In accordance with the present description, conductors 53B are laterally capacitively coupled to conductor 53C through dielectric 42 (shown for example, in FIG. 1) in space 124 as represented by capacitor C1.

FIGS. 5 and 6 graphically illustrate specific on-resistance (R_{SP})(mohm/mm 2) data as a function of breakdown voltage (BV_{DSS})(volts) comparing semiconductor devices in accordance with the present description with previous semiconductor devices. FIG. 5 illustrates data for N-channel semiconductor devices, and FIG. 6 illustrates data for P-channel semiconductor devices. In FIG. 5, curve 57 represents an average of data for previous N-channel semiconductor devices of various BV_{DSS} ratings, and data points 58 represent data for N-channel semiconductor devices of the present description for a 60 volt device and an 80 voltage device. As indicated by the data of FIG. 5, the N-channel semiconductor devices in accordance with the present description have a much lower R_{SP} performance compared to the previous semiconductor devices of similar breakdown voltage.

In FIG. 6, curve 67 represents an average of R_{SP} data for previous P-channel semiconductor devices of various BV_{DSS}, and data point 68 represents data for a P-channel semiconductor device in accordance with the present description for a 60 volt device. As indicated by the data of FIG. 6, the P-channel semiconductor device in accordance with the present description has a much lower R_{SP} performance compared to the previous semiconductor devices of similar breakdown voltage.

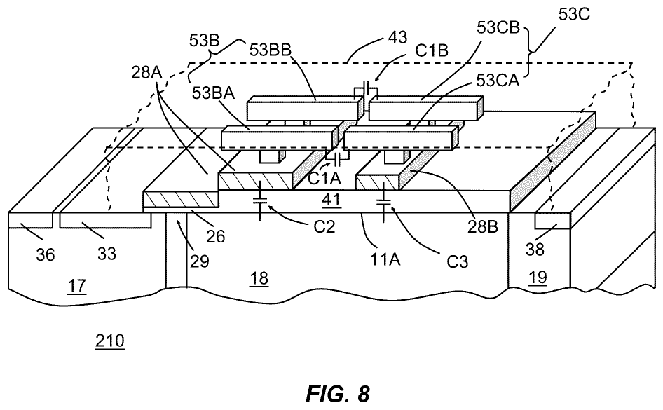

FIG. 7 illustrates a partial cross-sectional and perspective view a semiconductor device 200 in accordance with the present description that is configured for higher breakdown voltage (BV_{DSS}) performance, has improved specific on-resistance (R_{SP}), and is less susceptible to hot carrier injection (HCI). Semiconductor device 100 has some similarity of construction to semiconductor devices 10 and 100 and the similarity will not be repeated here. In this regard, only the distinctions between the semiconductor devices will be described.

In semiconductor device 200, conductor 53B comprises two or more portions, which are illustrated as conductor portions 53BA and 53BB. Also, conductor 53C comprises two or more portions, which are illustrated as conductor portions 53CA and 53CB. In addition, gate conductor 28B comprises two or more portions, which are illustrated as gate conductor portion 28BA and gate conductor portion 28BB. In the present example, gate conductor portion 28BA is laterally separated from gate conductor portion 28BB by a space or gap filled by, for example, dielectric 43. In the present example, conductor portion 53BA and conductor portion 53BB are coupled to gate conductor 28A (for example, both using a conductive interconnect 51C as shown in FIG. 1). Conductor 53CA is coupled to gate conductor 28BA and conductor 53CB is coupled to gate conductor 28BB (for example, both using a conductive interconnect 51D as shown in FIG. 1). In accordance with the present description, conductor 53BA is laterally capacitively coupled to conductor 53CA through dielectric 43 as represented by capacitor C1A, and conductor 53BB is laterally capacitively coupled to conductor 53CB through dielectric 43 as represented by capacitor C1B. Gate conductor 28BA is vertically capacitively coupled to well region 18 through dielectric 41 as represented by capacitor C3A, and gate conductor 28BB is vertically capacitively coupled to well region 18 through dielectric 41 as represented by capacitor C3B. It is understood that the capacitance values for capacitors C1A, C1B, C3A, and C3B can be set as described previously. Also, it is understood that conductor portion 53BA and conductor portion 53BA can be the same size or can be different sizes depending on the desired capacitive effects. Likewise, conductor portion 53CA and conductor portion 53CB can be the same size or be different sizes. In some examples, the configuration of gate conductor 28B (e.g., multiple portions) can allow for higher charge in well region 18 to facilitate additional reduction of on-resistance. The configuration of semiconductor device 200 can be used to further fine tune BV_{DSS}, R_{SP}, and HCI performance in accordance with present description.

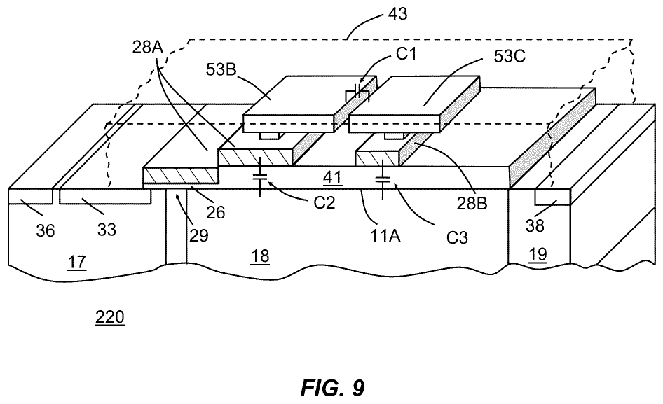

FIG. 8 illustrates a partial cross-sectional and perspective view a semiconductor device 210 in accordance with the present description that is configured for higher BV_{DSS} performance, has improved R_{SP}, and is less susceptible to HCI. Semiconductor device 210 has some similarity of construction to semiconductor device 200 and the similarity will not be repeated here. In this regard, only the distinctions between the semiconductor devices will be described. In semiconductor device 210, a continuous or single piece gate conductor 28B is used together with conductor portions 53CA and 53CB. The configuration of semiconductor device 210 can be used to further fine tune BV_{DSS}, R_{SP}, and HCI performance in accordance with present description.

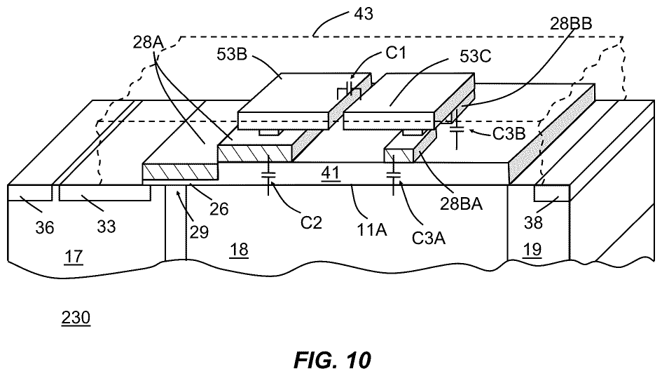

FIG. 9 illustrates a partial cross-sectional and perspective view of a semiconductor device 220 in accordance with the present description that is configured for higher BV_{DSS} performance, has improved R_{SP}, and is less susceptible to HCI. Semiconductor device 210 has some similarity of construction to semiconductor device 200 and semiconductor device 210 and the similarity will not be repeated here. In this regard, only the distinctions between the semiconductor devices will be described. In semiconductor device 220, conductor 53B is a single piece structure and conductor 53C is a continuous single piece structure. In some examples, conductor 53B and conductor 53C can have similar shapes and dimensions. In semiconductor device 220, gate conductor 28B is a single piece structure. In semiconductor device 220, conductor 53B is laterally capacitively coupled to conductor 53C as represented by capacitor C1. Conductor 53C is coupled to gate conductor 28B. Gate conductor 28A is vertically capacitively coupled to well region 28 as represented by capacitor C2, and gate conductor 28B is vertically capacitively coupled to well region 18 are represented by capacitor C3. In addition, that portion of conductor 53C overlying the space between gate conductor 28BA and gate conductor 28BB can be vertically capacitively coupled to well region 18 through dielectric 43 and dielectric 41 as represented by capacitor C4 (shown in FIG. 3). The configuration of semiconductor device 220 can be used to further fine tune BV_{DSS}, R_{SP}, and HCI performance in accordance with present description.

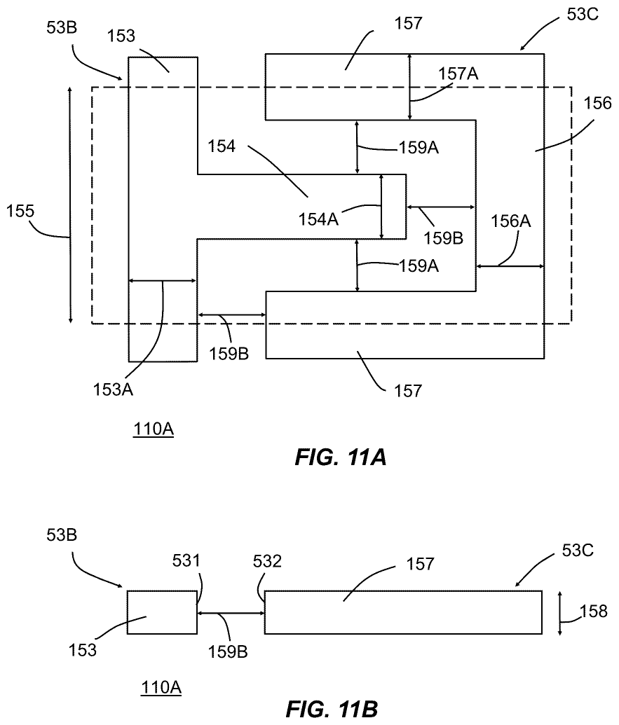

FIG. 10 illustrates a partial cross-sectional and perspective view of a semiconductor device 230 in accordance with the present description that is configured for higher BV_{DSS} performance, has improved R_{SP}, and is less susceptible to HCI. Semiconductor device 210 has some similarity of construction to semiconductor device 200 and semiconductor device 220 and the similarity will not be repeated here. In this regard, only the distinctions between the semiconductor devices will be described. In semiconductor device 230, gate conductor 28B comprises two or more portions, such as gate conductor portion 28BA and gate conductor portion 28BB. In semiconductor device 230, conductor 53C is coupled to conductor portion 28BA and to conductor portion 28BB (for example, using multiple interconnects 51D as shown in FIG. 1). Gate conductor 28BA is vertically capacitively coupled to well region 18 as represented by capacitor C3A, and gate conductor 28BB is vertically capacitively coupled to well region 18 as represented by capacitor C3B. The configuration of semiconductor device 230 can be used to further fine tune BV_{DSS}, R_{SP}, and HCI performance in accordance with present description.

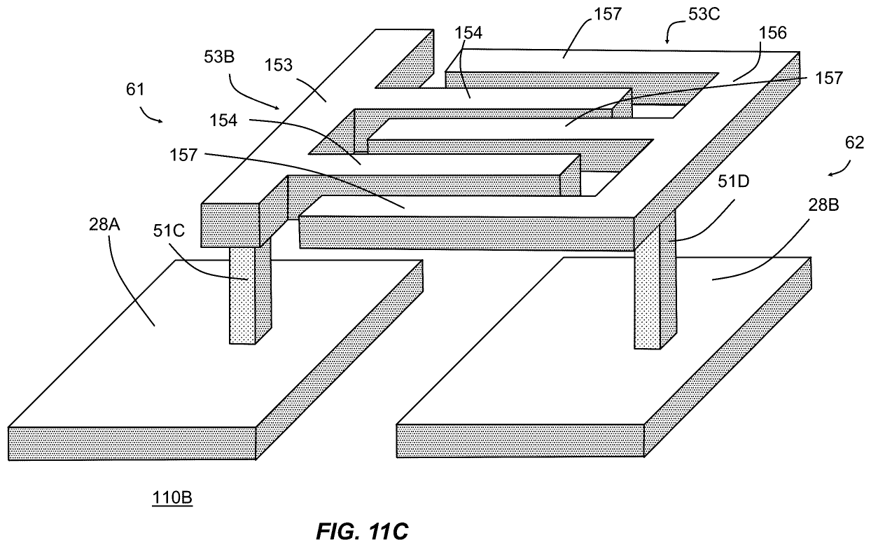

FIG. 11A illustrates a top plan view of a laterally capacitively coupled conductor structure 110A in accordance with the present description, and FIG. 11B illustrates a side view of the conductive structure of FIG. 11A. Conductor structure 110A can be used with the example semiconductor devices described herein. For example, conductor structure 110A can be used as part of gate conductor structures 61, 62, and 62. Conductor structure 110A comprises conductor 53B and conductor 53C in an interdigitated finger or comb-finger configuration, which can be used to increase the lateral capacitance between conductor 53B and 53C within an efficient area of the semiconductor device. In some examples, conductor structure 110A can be configured to fit within available space of about 0.35 microns to about 1.35 microns.

In some examples, conductor 53B comprises a base 153 and one or more fingers 154 extending from base 153. In some examples, conductor 53C comprises a base 156 and one or more fingers 157 extending from base 156 towards base 153. In some examples, base 153A has a width 153A and base 156 has width 156A, which can be the same or different. In some examples width 153A and 156A can be the same and can be in a range from about 0.10 microns to about 0.13 microns. In some examples, finger(s) 154 can have a width 154A and fingers 157 can have a width 157A, which can be the same or different. In some examples, width 154A and 157A can be the same and can be in a range from about 0.1 microns to about 0.2 microns. The sides of finger(s) 154 can be spaced from the sides of fingers 157 a width or space 159A. The end of finger(s) 154 and the end of fingers 157 can be spaced from base 156 and base 153 respectively a width or space 159B. In some examples, space 159A can be different than space 159B. In some examples, space 159A can be in a range from about 0.1 microns to about 0.3 microns and space 159B can be in a range from about 0.1 microns to about 0.2 microns. In some examples, space 159B is smaller than space 159A. In some examples, a dimension 155 can correspond to a distance from the centerline of one of fingers 157 to a centerline of an adjacent one of fingers 157. In some examples, dimension 155 can be in a range from 0.3 microns to about 0.4 microns. As illustrated in FIG. 11B, conductor 53B and conductor 53C can have a thickness 158 in range from about 0.1 microns to about 0.3 microns or more. FIG. 11B also illustrates element 532 as an end portion of finger 157 and element 531 as a side portion of base 153. All the foregoing dimensions can be variable to meet design requirements, and minimum values can be determined by process capabilities.

FIG. 11C illustrates a perspective view of a laterally capacitively coupled conductor structure 110B in accordance with the present description for gate conductor structure 61 and gate conductor structure 62. Conductor structure 110B has some similarity of construction to conductor structure 110A and the similarity will not be repeated here. In this regard, only the distinctions between the semiconductor devices will be described. In conductor substrate 110B, conductor 53B is configured with more than one finger 154 and conductor 53C is configured with more than two fingers 157 provided as an interdigitated finger or comb-finger configuration. FIG. 11C further illustrates conductor 53B coupled to gate conductor 28A using one or more conductive interconnects 51C, and conductor 54B coupled to gate conductor 28B using one or more conductive interconnects 51D.

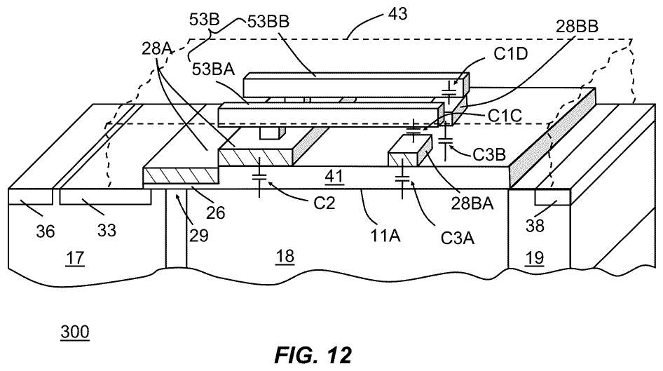

FIG. 12 illustrates a partial cross-sectional view and perspective view of an example semiconductor device 300 in accordance with the present description that is configured for higher BV_{DSS} performance, has improved R_{SP}, and is less susceptible to HCI. Semiconductor device 300 has some similarity of construction to semiconductor devices 10 and 100 and the similarity will not be repeated here. In this regard, only the distinctions between the semiconductor devices will be described. In some examples, semiconductor device 300 includes conductor 53B coupled to gate conductor 28A with one or more conductive interconnects 51C (shown in FIG. 1), but semiconductor device 300 does not include conductor 53C or conductive interconnects 51D. In addition, conductor 53B comprises two or more portions, which are illustrated as conductor portion 53BA and 53BB. Both conductor portions 53BA and 53BB are coupled to gate conductor 28A (for example, both using a conductive interconnect 51C as shown in FIG. 1). Further, gate conductor 28B comprises two or more portions, which are illustrated as gate conductor portion 28BA and 28BB. In the present example, gate conductor portion 28BA is laterally separated from gate conductor portion 28BB by a space or gap filled by, for example, dielectric 43.

In semiconductor device 300, conductor portion 53BA is vertically capacitively coupled to gate conductor portion 28BA through dielectric 43 as represented by capacitor C1C, and conductor portion 53BB is vertically capacitively coupled to gate conductor portion 28BB through dielectric 43 as represented by capacitor C1D. Gate conductor portion 28BA is vertically capacitively coupled to well region 18 through dielectric 41 as represented by capacitor C3A, and gate conductor portion 28BB is vertically capacitively coupled to well region 18 through dielectric 41 as represented by capacitor C3B. In some examples, the configuration of gate conductor 28B (e.g., multiple portions) can allow for higher charge in well region 18 to facilitate additional reduction of on-resistance. The configuration of semiconductor device 300 can be used to further fine tune BV_{DSS}, R_{SP}, and HCI performance in accordance with present description.

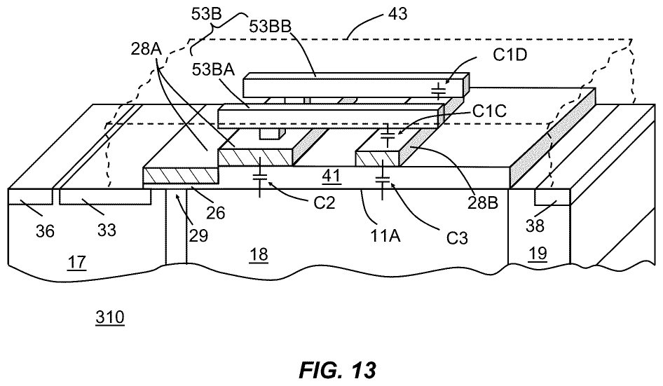

FIG. 13 illustrates a partial cross-sectional view and perspective view of an example semiconductor device 310 in accordance with the present description that is configured for higher BV_{DSS} performance, has improved R_{SP}, and is less susceptible to HCI. Semiconductor device 310 has some similarity of construction to semiconductor device 300 and the similarity will not be repeated here. In this regard, only the distinctions between the semiconductor devices will be described. In semiconductor device 310, a continuous or single piece structure is used for gate conductor 28B and both conductor portion 53BA and conductor portion 53BB are vertically capacitively coupled to gate conductor 28B as represented by capacitors C1C and C1D. In some examples, both conductor portion 53BA and conductor portion 53BB can laterally extend beyond gate conductor 28B and can be vertically capacitively coupled to well region through dielectric 43 and dielectric 41 to provide additional electric field shaping or control as represented by capacitor(s) C4 (shown in FIG. 3). The configuration of semiconductor device 310 can be used to further fine tune BV_{DSS}, R_{SP}, and HCI performance in accordance with present description.

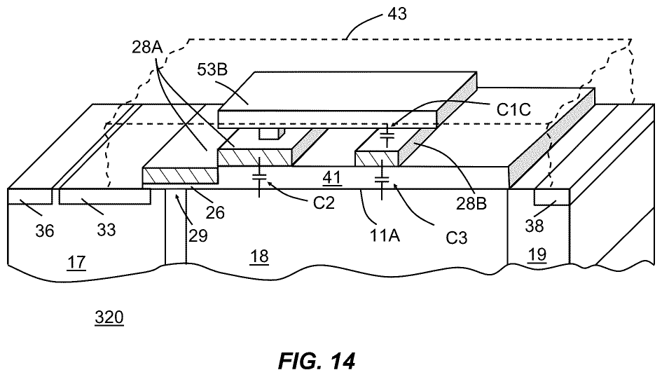

FIG. 14 illustrates a partial cross-sectional view and perspective view of an example semiconductor device 320 in accordance with the present description that is configured for higher BV_{DSS} performance, has improved R_{SP}, and is less susceptible to HCI. Semiconductor device 320 has some similarity of construction to semiconductor device 310 and the similarity will not be repeated here. In this regard, only the distinctions between the semiconductor devices will be described. In semiconductor device 320, conductor 53B is provided as a continuous or single-piece structure, which is vertically capacitively coupled to gate conductor 28B as represented by capacitor C1C. The configuration of semiconductor device 320 can be used to further fine tune BV_{DSS}, R_{SP}, and HCI performance in accordance with present description.

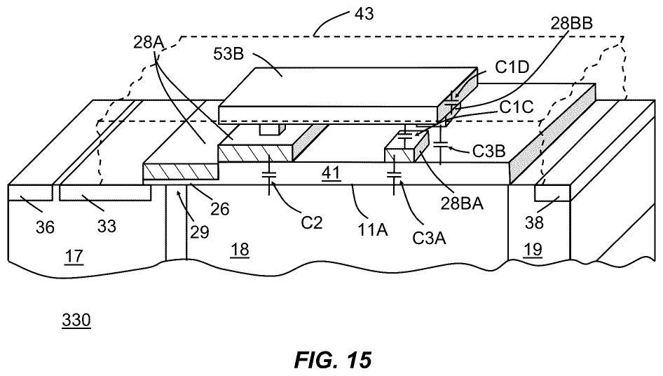

FIG. 15 illustrates a partial cross-sectional view and perspective view of an example semiconductor device 330 in accordance with the present description that is configured for higher BV_{DSS} performance, has improved R_{SP}, and is less susceptible to HCI. Semiconductor device 330 has some similarity of construction to semiconductor devices 310 and 320 and the similarity will not be repeated here. In this regard, only the distinctions between the semiconductor devices will be described. In semiconductor device 330, gate conductor 28B comprises two or more portions, which are illustrated as gate conductor portion 28BA and 28BB. In the present example, gate conductor portion 28BA is laterally separated from gate conductor portion 28BB by a space or gap filled by, for example, dielectric 43. Conductor 53B is provided as a continuous or single-piece structure, which is vertically capacitively coupled to gate conductor 28BA as represented by capacitor C1C, and vertically capacitively coupled to gate conductor 28BB as represented by capacitor C1D. Gate conductor portion 28BA is vertically capacitively coupled to well region 18 through dielectric 41 as represented by capacitance C3A, and gate conductor portion 28BB is vertically capacitively coupled to well region 18 as represented by capacitance C3B. In addition, that portion of conductor 53B overlying the space between gate conductor 28BA and gate conductor 28BB can be vertically capacitively coupled to well region 18 through dielectric 43 and dielectric 41 as represented by capacitor C4 (shown in FIG. 3). The configuration of semiconductor device 330 can be used to further fine tune BV_{DSS}, R_{SP}, and HCI performance in accordance with present description.

In summary, a semiconductor device having improved BV_{DSS}, R_{SP}, and HCI performance and associated method has been described. The semiconductor device comprises capacitively coupled gate conductor structures that are configured to control electric field build-up in portions of the semiconductor device. In some examples, the capacitively coupled gate conductor structures are formed over a dielectric having a selected thickness and structure that reduces hot carrier injection at higher breakdown voltages. In addition, the dielectric improves specific on-resistance at higher breakdown voltages by providing a larger path for current flow. The structure and method according to the present disclosure can be used without expensive silicon on insulator (SOI), shallow trench isolation (STI), or localized oxidation (LOCOS) type isolations. This provides for, among other things, a cost effective and reliable implementation for smaller process nodes and for application that have higher reliability requirements, such as automotive applications. In some examples, the semiconductor device is an LDMOS device.

It is understood that the different examples described herein can be combined with any of the other examples described herein to obtain different embodiments.

While the subject matter of the invention is described with specific preferred examples, the foregoing drawings and descriptions thereof depict only typical examples of the subject matter and are not therefore to be considered limiting of its scope. It is evident that many alternatives and variations will be apparent to those skilled in the art. For example, the conductivity types of the various regions can be reversed. In addition, other isolation techniques can be used to isolate the active device regions. It is understood that the term semiconductor substrate can refer to an individual semiconductor die, a plurality of semiconductor die, or a semiconductor wafer.

As the claims hereinafter reflect, inventive aspects may lie in less than all features of a single foregoing disclosed example. Thus, the hereinafter expressed claims are hereby expressly incorporated into this Detailed Description of the Drawings, with each claim standing on its own as a separate example of the invention. Furthermore, while some examples described herein include some, but not other features included in other examples, combinations of features of different examples are meant to be within the scope of the invention and meant to form different examples as would be understood by those skilled in the art.

What is claimed is:

1. A semiconductor device, comprising:
a region of semiconductor material;
a first dielectric over the region of semiconductor material;
a first gate conductor over a first portion of the first dielectric;
a second gate conductor over a second portion of the first dielectric and laterally spaced apart from the first gate conductor;
a first conductor coupled to the first gate conductor;
a second conductor coupled to the second gate conductor and laterally separated from the first conductor by a first spacing; and
a second dielectric within the first spacing;
wherein:
the first conductor and the second conductor are laterally capacitively coupled;
the first gate conductor is vertically capacitively coupled to the region of semiconductor material; and
the second gate conductor is vertically capacitively coupled to the region of semiconductor material.

2. The semiconductor device of claim 1, wherein:
the region of semiconductor material comprises:
a semiconductor substrate; and
a semiconductor region having a first conductivity type over the semiconductor substrate;
the semiconductor device further comprises:
a first well region of the first conductivity type in the region of semiconductor;
a second well region of a second conductivity type opposite to the first conductivity type in the region of semiconductor material;
a first doped region of the second conductivity type in the first well region;
a second doped region of the second conductivity type in the second well region;
a channel region between the first doped region and the second well region; and
a gate dielectric over the channel region;
the first dielectric is over the second well region between the gate dielectric and the second doped region;
the first gate conductor is over the gate dielectric; and
the second gate conductor is interposed between the first gate conductor and the second doped region.

3. The semiconductor device of claim 1, wherein:
the first dielectric comprises a first thickness configured so that the first gate conductor over the first portion of the first dielectric and the second gate conductor over the second portion of the first dielectric control an electric field within the region of semiconductor material responsively to a voltage applied to the first gate conductor.

4. The semiconductor device of claim 1, wherein:
the first dielectric comprises a non-recessed dielectric.

5. The semiconductor device of claim 4, wherein;
the first dielectric comprises a first thickness in a range from about 1000 Angstroms to about 1200 Angstroms.

6. The semiconductor device of claim 1, wherein:
the second gate conductor comprises:
a second gate conductor first portion; and
a second gate conductor second portion laterally separated from the second gate conductor first portion; and
the second conductor is coupled to the second gate conductor first portion; and
the second conductor is coupled to the second gate conductor second portion through a second conductive via.

7. The semiconductor device of claim 1, further comprising:
a third conductor coupled to the first gate conductor; and
a fourth conductor coupled to the second gate conductor and laterally separated from the third conductor by a second spacing;
wherein:
the second dielectric is within the second spacing; and
the third conductor and the fourth conductor are laterally capacitively coupled.

8. The semiconductor device of claim 1, wherein:
the first conductor has a first conductor lateral end adjoining the second dielectric within the first spacing;
the second conductor has a second conductor lateral end adjoining the second dielectric within the first spacing;
the first conductor lateral end faces the second conductor lateral end;
the first conductor lateral end is a first capacitive plate;
the second conductor latera end is a second capacitive plate; and
the first capacitive plate, the second dielectric within the first spacing, and the second capacitive plate form a first capacitor.

9. The semiconductor device of claim 8, wherein:
the second dielectric is over the first dielectric;
the second conductor extends over the second dielectric and the first dielectric; and
the second conductor, the second dielectric, the first dielectric, and the region of semiconductor material form a second capacitor.

10. The semiconductor device of claim 1, wherein:
the first spacing is in a range from about 0.1 microns to about 0.3 microns.

11. The semiconductor device of claim 1, wherein:
the first conductor comprises a first base with at least one finger extending laterally away from the base toward the second conductor; and
the second conductor comprises a second base with at least one finger extending towards the first conductor.

12. A semiconductor device, comprising:
a region of semiconductor material comprising a first conductivity type;
a gate dielectric adjacent to the region of semiconductor material;
a first dielectric adjacent to the region of semiconductor material;
a first gate electrode over the gate dielectric and over a first portion of the first dielectric;
a second gate electrode over a second portion of the first dielectric and laterally spaced apart from the first gate electrode;
a first conductor coupled to the first gate electrode;
a second conductor coupled to the second gate electrode and laterally separated from the first conductor by a space; and
a second dielectric within the space;
wherein:
the first conductor is capacitively coupled to the second conductor across the space in a first direction; and
the second gate electrode is capacitively coupled to the region of semiconductor material in a second direction different than the first direction.

13. The semiconductor device of claim 12, wherein:
the first conductor comprises a first base and a first finger extending from the first base;
the first finger comprises a first finger side;
the second comprises a second base and a second finger extending from the second base towards the first base;
the second finger comprises a second finger side;
the second finger side is proximate the first finger side; and
the second finger side is separated from the first finger side by the space.

14. The semiconductor device of claim 12, wherein:
the second gate electrode comprises:
a second gate electrode first portion; and
a second gate electrode second portion laterally separated from the second gate electrode first portion by a gap;
a portion of the second conductor overlaps the gap; and
the portion is capacitively coupled to the region of semiconductor material.

15. The semiconductor device of claim 12, wherein:
the first dielectric has a thickness in a range from about 800 Angstroms to about 2000 Angstroms.

16. The semiconductor device of claim 12, wherein:
the second gate electrode has an edge distal to the gate dielectric;
a portion of the second conductor overlaps the edge; and
the portion is capacitively coupled to the region of semiconductor material.

17. The semiconductor device of claim 12, wherein:
the first gate electrode over the first portion of the first dielectric is capacitively coupled to the region of semiconductor material in the second direction.

18. A method of manufacturing a semiconductor device, comprising:
providing a region of semiconductor material comprising a first conductivity type;
providing a gate dielectric adjacent to the region of semiconductor material;
providing a first dielectric adjacent to the region of semiconductor material;
providing a first gate electrode over the gate dielectric and over a first portion of the first dielectric;
providing a second gate electrode over a second portion of the first dielectric and laterally spaced apart from the first gate electrode;
providing a first conductor electrically connected to the first gate electrode;
providing a second conductor electrically connected to the second gate electrode and laterally separated from the first conductor by a space; and
providing a second dielectric in the space;
wherein:
the first conductor is capacitively coupled to the second conductor across the space in a first direction;
the first gate electrode over the first portion of the first dielectric is capacitively coupled to the region of semiconductor material in a second direction; and
the second gate electrode is capacitively coupled to the region of semiconductor material in the second direction.

19. The method of claim 18, wherein:
providing the first conductor comprises:
providing a first base and a first finger extending from the first base; and
providing the first finger comprising a first finger side; and
providing the second conductor comprises:
providing a second base and a second finger extending from the second base towards the first base;
providing the second finger comprises a second finger side;
providing the second finger side is proximate the first finger side; and
providing the second finger side separated from the first finger side by the space.

20. The method of claim 18, wherein:
providing the first dielectric comprises forming an oxide comprising a thickness in a range from about 800 Angstroms to about 2000 Angstroms.
